(19) United States
(12) Patent Application Publication
(10) Pub. No.: US 2024/0279540 A1
(43) Pub. Date: Aug. 22, 2024

(54) QUANTUM DOT COMPOSITE, INK COMPOSITION INCLUDING THE SAME, LIGHT-EMITTING DEVICE INCLUDING THE QUANTUM DOT COMPOSITE, OPTICAL MEMBER INCLUDING THE QUANTUM DOT COMPOSITE, AND APPARATUS INCLUDING THE QUANTUM DOT COMPOSITE

(71) Applicant: Samsung Display Co., Ltd., Yongin-si (KR)

(72) Inventors: Juo Nam, Yongin-si (KR); Joonhyung Kim, Yongin-si (KR); Kawon Pak, Yongin-si (KR); Kyungsig Lee, Yongin-si (KR); Taekjoon Lee, Yongin-si (KR); Seunghee Jang, Yongin-si (KR); Jaebok Chang, Yongin-si (KR)

(21) Appl. No.: 18/490,665

(22) Filed: Oct. 19, 2023

(30) Foreign Application Priority Data
Feb. 6, 2023 (KR) 10-2023-0015715

(51) Int. Cl. C09K 11/08; C09D 11/03; C09K 11/06; H10K 50/115

(52) U.S. Cl. CPC C09K 11/08; C09D 11/03; C09K 11/06; H10K 50/115

(57) ABSTRACT

A quantum dot composite including a quantum dot and a quantum dot ligand located on a surface of the quantum dot is provided. The quantum dot ligand includes a hydrophilic linking portion including an oxygen atom, a bonding portion linked to one side of the linking portion and including different functional groups bonded to the quantum dot, and a terminal portion linked to the linking portion at a side opposite to the linking portion. The quantum dot ligand is configured to prevent or reduce aggregation of quantum dots and improve their dispersion in a solvent thereby improving the light and/or heat resistance of electronic apparatus that utilize the quantum dot composite.

### CROSS-REFERENCE TO RELATED APPLICATION

This application claims priority to and the benefit of Korean Patent Application No. 10-2023-0015715, filed on Feb. 6, 2023, in the Korean Intellectual Property Office, the disclosure of which is incorporated by reference herein in its entirety.

### BACKGROUND

### 1. Field

One or more aspects of embodiments of the present disclosure relate to a quantum dot composite, an ink composition including the same, a light-emitting device, an optical member, and an apparatus.

### 2. Description of the Related Art

Quantum dots are nano crystals of a semiconductor material and are materials that exhibit a quantum confinement effect. When quantum dots receive light from an excitation source and reach an energy excited state, the quantum dots spontaneously emit energy according to a corresponding energy band gap. In this case, quantum dots of the same material may emit light having different wavelengths depending on the size of the quantum dots. Accordingly, the size of quantum dots may be adjusted to obtain light in a desired or suitable wavelength range and exhibit characteristics such as excellent or suitable color purity and high luminous efficiency. Therefore, quantum dots are applicable to one or more suitable devices.

In some embodiments, quantum dots may be utilized as materials performing one or more suitable optical functions (for example, a photoconversion function) of optical members. Optical members including such a quantum dot may have a thin film form, for example, a thin film form patterned for each subpixel. Such an optical member may also be utilized as a color conversion member of an apparatus including one or more suitable light sources.

In manufacturing of quantum dot devices, it is important to prevent or reduce aggregation of quantum dots in a quantum dot composition and to improve or secure a degree of dispersion in a solvent. Although quantum dot ligands are utilized for this purpose, the quantum dot ligands may be deteriorated by light or heat, and thus the reliability of quantum dot devices may deteriorate.

### SUMMARY

One or more aspects of embodiments of the present disclosure are directed toward a quantum dot ligand with improved light resistance or heat resistance and a quantum dot composite including the same.

One or more aspects of embodiments of the present disclosure are directed toward an ink composition, a light-emitting device, an optical member, and an apparatus which include a quantum dot composite having improved light resistance or heat resistance.

One or more aspects of embodiments of the present disclosure are directed toward a quantum dot composite for use in an ink composition, a light-emitting device, an optical member, and an electronic apparatus. Additional aspects will be set forth in part in the description which follows and, in part, will be apparent from the description, or may be learned by practice of the presented embodiments of the disclosure.

According to one or more embodiments, a quantum dot composite includes a quantum dot and a quantum dot ligand provided on a surface of the quantum dot. The quantum dot ligand may include a hydrophilic linking portion including one or more oxygen atoms, a bonding portion linked to one side of the hydrophilic linking portion and including different functional groups bonded to the quantum dot, and a terminal portion linked to the hydrophilic linking portion at a side opposite to the linking portion.

The different functional groups bonded to the quantum dot may be selected from among —COOH, —OH, —SH, and —NH₂.

In one or more embodiments, the quantum dot ligand may be represented by Formula 1.

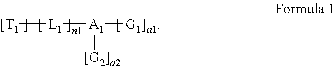

In Formula 1,

L₁ may be the hydrophilic linking portion including the oxygen atom,

A₁ may be the bonding portion (i.e., to which the different functional groups bonded to the quantum dot are bonded),

G₁ and G₂ may be the different functional groups (i.e., selected from among —COOH, —OH, —SH, and NH₂),

T₁ may be the terminal portion which is not bonded to the quantum dot,

n1 may be an integer from 1 to 10.

a₁ and a₂ may each independently be 1 or 2, and a₁+a₂ may be 3 or less.

In one or more embodiments, the hydrophilic linking portion may include an ethylene glycol unit (CH₂CH₂O) or a propylene glycol unit (CH₂CH(CH₃)O or CH₂CH₂CH₂O).

In one or more embodiments, the bonding portion may include a C₂-C₅ alkyl group or a C₂-C₅ alkenyl group.

In one or more embodiments, in the bonding portion (e.g., in A₁), a carbon atom to which the functional group G₁ is bonded and a carbon atom to which the functional group G₂ is bonded may be adjacent to each other.

In other embodiments, in the bonding portion (e.g., in A₁), a C₁-C₃ moiety may link a carbon atom to which the functional group G₁ is bonded and a carbon atom to which the functional group G₂ is bonded.

In one or more embodiments, the bonding portion (e.g., A₁) may include C(═O)C(*)HC(**)H₂, wherein the C(*) and C(**) represent carbon atoms to which the different functional groups are bonded.

In one or more embodiments, a combination of the functional group G₁ and the functional group G₂ may be selected from among (—COOH, —SH), (—SH, —COOH), (—COOH, —OH), (—OH, —COOH), (—COOH, —NH₂), (—NH₂, —COOH), (—SH, —NH₂), and (—NH₂, —SH).

In one or more embodiments, the terminal portion may include a hydroxyl group, an amine group, a sulfonic acid group, a phosphoric acid group, an ammonium group, a phosphonium group, a C₁-C₂₀ alkyl group, a C₁-C₂₀ alkoxy group, a C₆-C₂₀ aryl group, a C₂-C₂₀ heteroaryl group, or a C₇-C₂₀ aryl alkyl group.

In one or more embodiments, the quantum dot ligand may include any one selected from among compounds below:

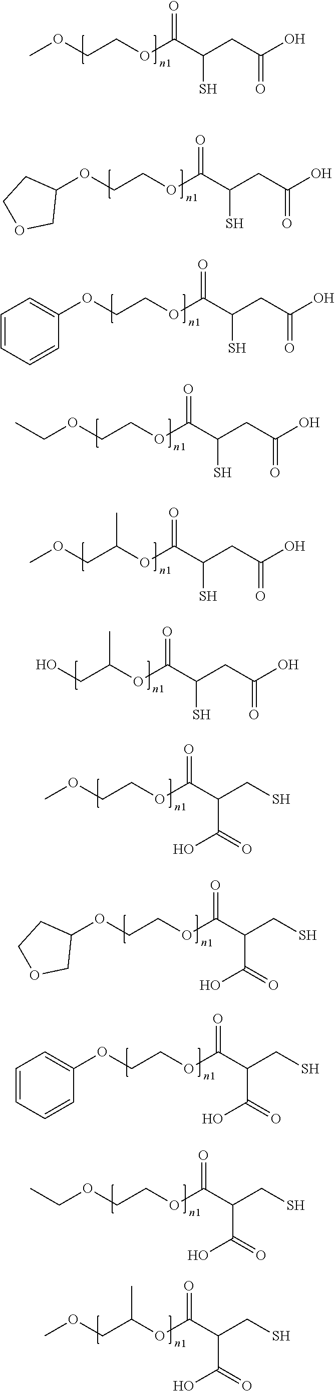

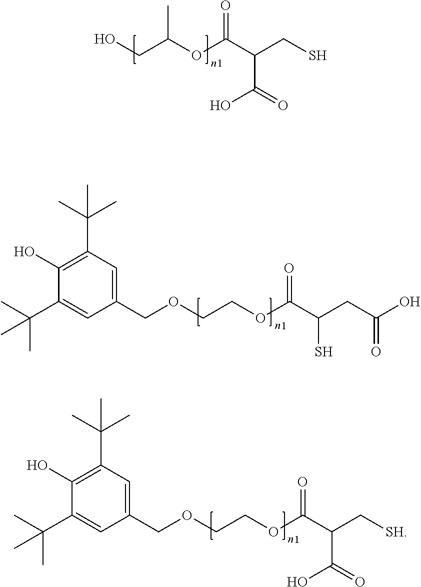

In one or more embodiments, the different functional groups of the quantum dot ligand may be bonded to different atoms on the surface of the quantum dot, respectively.

In other embodiments, the different functional groups of the quantum dot ligand may be bonded to one atom on the surface of the quantum dot.

In one or more embodiments, the quantum dot may have a core-shell structure which includes a core including a first semiconductor material and a shell including a second semiconductor material and the shell is around (e.g., surrounding) the core.

In one or more embodiments, the first semiconductor material and the second semiconductor material may each independently include (e.g., be selected from among):
ZnS, ZnSe, ZnTe, ZnO, MgSe, MgS, ZnSeS, ZnSeTe, ZnSTe, MgZnSe, MgZnS, or CdZnSeS,
GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InGaN, InGaP, InNP, InAlP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, InGaZnP, or InAIZnP,
TiO, GaO, GaS, GaSe, Ga₂Se₃, GaTe, InS, InSe, In₂S₃, In₂Se₃, or InTe,
InGaS₃ or InGaSe₃,
AgInS, AgInS₂, CuInS, CuInS₂, CuGaO₂, AgGaO₂, AgAlO₂, or AgInZnS,
SrSe, SnS, SnSe, SnTe, PbS, PbSe, or PbTe; SnSeS, SnSeTe, SnSTe, PbSeS, PbSeTe, PbSTe, SnPbS, SnPbSe, SnPbTe, SnPbSSe, SnPbSeTe, or SnPbSTe, and/or
Si, Ge, SiC, SiGe, or any combination thereof.

According to one or more embodiments, an ink composition includes the above-described quantum dot composite and a crosslinkable monomer.

According to one or more embodiments, a light-emitting device includes a first electrode, a second electrode opposite to the first electrode, and an intermediate layer provided between the first electrode and the second electrode, wherein the intermediate layer includes the above-described quantum dot composite.

According to one or more embodiments, an optical member includes the above-described quantum dot composite.

In one or more embodiments, the optical member may be a color conversion member.

According to one or more embodiments, an apparatus includes the above-described quantum dot composite.

In one or more embodiments, the apparatus may further include a light source, and the quantum dot composite may be provided on a path of light emitted from the light source.

### BRIEF DESCRIPTION OF THE DRAWINGS

The accompanying drawings are included to provide a further understanding of the above and other aspects, features, and advantages of certain embodiments of the present disclosure are incorporated in and constitute a part of this specification. The drawings illustrate example embodiments and, together with the following description taken in conjunction with the accompanying drawings, serve to make the principles of the present disclosure more apparent. In the drawings:

FIG. 1 is a schematic cross-sectional view of a light-emitting device according to one or more embodiments of the present disclosure;

FIG. 2 is a schematic cross-sectional view of an electronic apparatus according to one or more embodiments of the present disclosure; and

FIG. 3 is a schematic cross-sectional view of an electronic apparatus according to one or more embodiments of the present disclosure.

### DETAILED DESCRIPTION

Reference will now be made in more detail to embodiments, examples of which are illustrated in the accompanying drawings, wherein like reference numerals refer to like elements throughout, and duplicative descriptions thereof may not be provided. In this regard, the present embodiments may have different forms and should not be construed as being limited to the descriptions set forth herein. Accordingly, the embodiments are merely described, by referring to the drawings, to explain aspects of the present description.

As utilized herein, the term “and/or” includes any and all combinations of one or more of the associated listed items. Expressions such as “at least one of,” “one of,” and “selected from,” when preceding a list of elements, modify the entire list of elements and do not modify the individual elements of the list. For example, throughout the disclosure, the expression “at least one of a, b or c” indicates only a, only b, only c, both (e.g., simultaneously) a and b, both (e.g., simultaneously) a and c, both (e.g., simultaneously) b and c, all of a, b, and c, or variations thereof.

Because the disclosure can apply one or more suitable transformations and have one or more suitable embodiments, specific embodiments will be illustrated in the drawings and described in more detail in the detailed description. The effects and features of the disclosure and methods of accomplishing the same will become apparent from the following description of the embodiments in more detail, taken in conjunction with the accompanying drawings. The disclosure may, however, be embodied in many different forms and should not be construed as limited to the embodiments set forth herein.

The terminology used herein is for the purpose of describing embodiments and is not intended to limit the embodiments described herein. Unless otherwise defined, all chemical names, technical and scientific terms, and terms defined in common dictionaries should be interpreted as having meanings consistent with the context of the related art, and should not be interpreted in an ideal or overly formal sense.

Hereinafter, embodiments of the present disclosure will be described in more detail with reference to the accompanying drawings, wherein like reference numerals refer to the same or corresponding components throughout the drawings, and a redundant description thereof will not be provided.

In the following embodiments, the terms first, second, and/or the like do not have limited meaning but are utilized for the purpose of distinguishing one component from another component. These terms are only used to distinguish one element from another element. Thus, a first element could be termed a second element without departing from the teachings of the present disclosure. Similarly, a second element could be termed a first element.

In the following embodiments, the expressions utilized in the singular such as “a,” “an,” and “the” are intended to include the plural forms as well, unless the context clearly indicates otherwise.

In the following embodiments, it will be understood that the terms such as “include,” “includes,” “including,” “comprise,” “comprises,” “comprising,” “has,” “have,” and “having” specify the presence of stated features or components, but do not preclude the presence or addition of one or more other steps, operations, elements, components, features, groups, and/or components thereof.

As used herein, the terms “use,” “using,” and “used” may be considered synonymous with the terms “utilize,” “utilizing,” and “utilized,” respectively.

As used herein, the term “and/or” includes any, and all, combination(s) of one or more of the associated listed items.

The term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

In the following embodiment, it will be understood that when an element such as a layer, film, region, or substrate is referred to as being “connected to,” or ‘on’ another element, it can be directly connected to, or on, the other element or intervening elements may also be present. When an element is referred to as being “directly on,” “directly connected to,” or “directly coupled to” another element, there are no intervening elements present. In some embodiments, for convenience of description, components may be exaggerated or reduced in size in the drawings. For example, the sizes and thicknesses of the respective components shown in the drawings are arbitrarily shown for convenience of description, and thus the disclosure is not necessarily limited thereto.

Spatially relative terms, such as “beneath,” “below,” “lower,” “above,” “upper,” “bottom,” “top,” and the like, may be used herein for ease of description to describe one element or feature's relationship to another element(s) or feature(s) as illustrated in the drawings. It will be understood that the spatially relative terms are intended to encompass different orientations of the device in use or operation in addition to the orientation depicted in the drawings. For example, if the device in the drawings is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

Unless otherwise defined, all terms (including technical and scientific terms) used herein have the same meaning as commonly understood by those of ordinary skill in the art to which the present disclosure pertains. It is also to be understood that terms defined in commonly used dictionaries should be interpreted as having meanings consistent with meanings in the context of the related art, unless expressly defined herein, and should not be interpreted in an ideal or overly formal sense.

In this context, “consisting essentially of” means that any additional components will not materially affect the chemical, physical, optical or electrical properties of the semiconductor film.

Further, in this specification, the phrase “on a plane,” or “plan view,” means viewing a target portion from the top, and the phrase “on a cross-section” means viewing a cross-section formed by vertically cutting a target portion from the side.

As utilized herein, “quantum dot ligand” refers to a ligand bonded to or provided on a surface of a quantum dot as well as a compound usable as a ligand of a quantum dot.

As utilized herein, “quantum dot composite” refers to a composite including a quantum dot. For example, “quantum dot composite” refers to a quantum dot of which a surface is passivated by a quantum dot ligand.

As utilized herein, “C₁-C₃” moiety refers to a moiety having 1 to 3 carbon atoms. Similarly, as utilized herein, “C₁-C₃₀ alkyl group” refers to an alkyl group having 1 to 30 carbon atoms. Such a method of expressing the number of carbon atoms is also applied to other substituents.

### Quantum Dot Ligand

According to an aspect, there is provided a quantum dot ligand including a hydrophilic linking portion which includes one or more oxygen atoms, a bonding portion which is linked (e.g., bonded) to the hydrophilic linking portion and includes different functional groups bonded to a quantum dot, and a terminal portion which is linked (e.g., coupled) to the hydrophilic linking portion and includes a functional group not bonded to the quantum dot.

The hydrophilic linking portion of the quantum dot ligand may allow a quantum dot composite (e.g., a ligand-passivated quantum dot composite) to be well dispersed in a polar ink composition and maintain dispersion stability for a long time.

The quantum dot ligand may include the different functional groups bonded to the quantum dot. In one or more embodiments, the different functional groups may be selected from among —COOH, —OH, —SH, and —NH₂. In one or more embodiments, the —COOH, —OH, —SH, and —NH₂ may (e.g., each) be bonded to a metal ion on a surface of the quantum dot to enable the quantum dot ligand to passivate the surface of the quantum dot.

Existing quantum dot ligands having a single type or kind of functional group bonded to a quantum dot may have low light stability or thermal stability, and thus the reliability of a quantum dot composite may deteriorate. For example, a quantum dot ligand including only a thiol group (—SH) as a functional group bonded to a quantum dot is advantageous in that the thiol group is strongly bonded to the quantum dot to form a quantum dot composite. However, because the thiol group does not have sufficient stability against light irradiation, the ligand may be easily detached from the quantum dot, and as a result, photoconversion efficiency (PCE) of the quantum dot composite may be lowered. For another example, in the case of a quantum dot ligand including a carboxylic acid group (—COOH) as a functional group bonded to a quantum dot, the carboxylic acid group may be easily deteriorated by heat. Therefore, when a quantum dot film is formed, the PCE of a quantum dot composite may be lowered due to deterioration in a baking process after film coating. In some embodiments, quantum dots may have one or more suitable crystal facets according to a component or a forming process, and functional groups that are easily bonded may be different according to crystal facets.

Because the quantum dot ligand according to the present embodiment includes the different functional groups at the same time, the quantum dot ligand may be stably bonded to a quantum dot under one or more suitable conditions of light irradiation, heat treatment, crystal facets, and/or the like, thereby securing the stability of a quantum dot composite.

When the different functional groups are positioned adjacent to each other, bonding of the different functional groups to metal atoms of the quantum dot is possible through a divalent linkage. In some embodiments, the divalent linkage may have a “bridge form” in which the different functional groups are respectively bonded to different metal ions. In some embodiments, the divalent linkage may have a “chelate form” in which each of the different functional groups is bonded to one metal ion.

The terminal portion may be linked to the hydrophilic linking portion at a side opposite to the bonding portion. Accordingly, when the quantum dot ligand and the quantum dot form a quantum dot composite, the terminal portion may be positioned at an outermost side of the quantum dot composite. The terminal portion may be appropriately selected such that the quantum dot composite is well dispersed in a dispersion.

In one or more embodiments, the quantum dot ligand may be a compound represented by Formula 1.

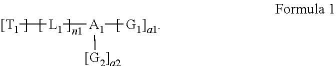

In Formula 1,

L₁ may be the hydrophilic linking portion including the oxygen atom,

A₁ may be the bonding portion (i.e., to which different functional groups (e.g., G₁ and G₂) bonded to the quantum dot are bonded), and

T₁ may be the terminal portion which is not bonded to the quantum dot.

G₁ and G₂ may be the different functional groups and may be selected from among —COOH, —OH, —SH, and NH₂.

n1 may be an integer from 1 to 10.

a₁ and a₂ may each independently be 1 or 2, and a₁+a₂ may be 3 or less.

In one or more embodiments, the linking portion or L₁ may include an ethylene glycol unit (e.g., CH₂CH₂O) or a propylene glycol unit (e.g., CH₂CH(CH₃)O or CH₂CH₂CH₂O), but one or more embodiments are not limited thereto.

In one or more embodiments, the bonding portion (e.g., A₁) may include a C₂-C₅ alkyl group or a C₂-C₅ alkenyl group.

In one or more embodiments, a carbon atom to which G₁ is bonded and a carbon atom to which G₂ is bonded may be adjacent to each other in A₁.

In other embodiments, the carbon atom to which G₁ is bonded and the carbon atom to which G₂ is bonded in A₁ may be separated by a C₁-C₃ moiety. For example, the carbon atom to which G₁ is bonded and the carbon atom to which G₂ is bonded in A₁ may be linked through the C₁-C₃ moiety.

In one or more embodiments, the bonding portion (e.g., A₁) may include C(═O)C(*)HC(**)H₂. In this case, C(*) and C(**) represent carbon atoms to which the different functional groups are bonded. For example, in C(═O)C(*)HC(**)H₂, the carbon atoms to which the different functional groups are bonded may be adjacent to each other.

In one or more embodiments, a combination of G₁ and G₂ may be selected from among (—COOH, —SH), (—SH, —COOH), (—COOH, —OH), (—OH, —COOH), (—COOH, —NH₂), (—NH₂, —COOH), (—SH, —NH₂), and (—NH₂, —SH). For example, when the combination of G₁ and G₂ is (—COOH, —SH), G₁ may be —COOH, and G₂ may be —SH. When the combination of G₁ and G₂ is (—SH, —COOH), G₁ may be —SH, and G₂ may be —COOH.

The terminal portion (e.g., T₁) may include, for example, be selected from among a hydroxyl group, an amine group, a sulfonic acid group, a phosphoric acid group, an ammonium group, a phosphonium group, a C₁-C₂₀ alkyl group, a C₁-C₂₀ alkoxy group, a C₆-C₂₀ aryl group, a C₂-C₂₀ heteroaryl group, and/or a C₇-C₂₀ aryl alkyl group. The terminal portion may include (e.g., be selected from among) a hydroxyl group, a methoxy group, a tetrahydrofuranyl group, and/or a phenoxide group, but one or more embodiments are not limited thereto.

In one or more embodiments, the quantum dot ligand may include any one selected from among the following compounds, but one or more embodiments are not limited thereto,

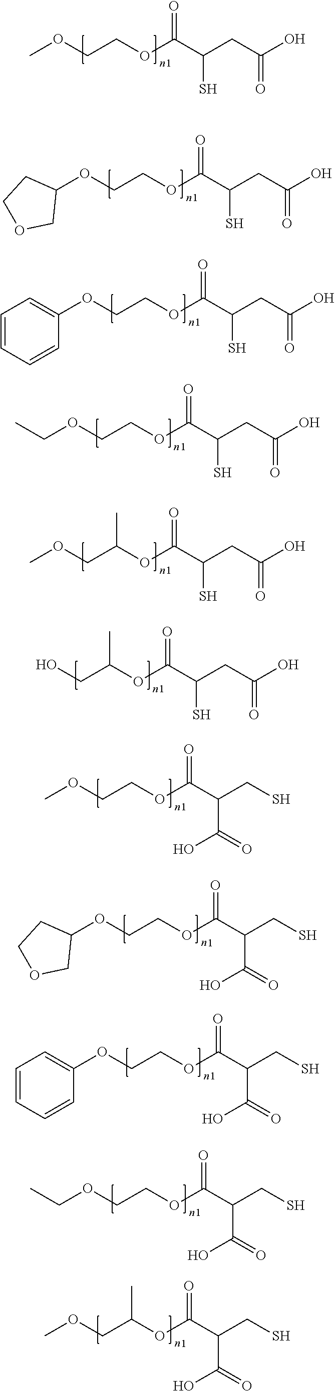

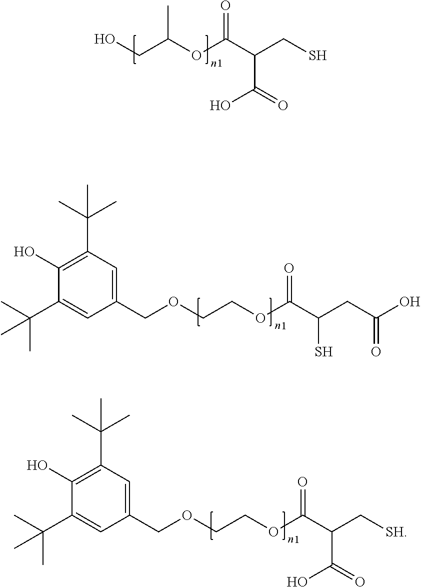

### Quantum Dot Composite

According to another aspect, there is provided a quantum dot composite including the described quantum dot ligand.

The quantum dot composite may include a quantum dot and the one or more quantum dot ligands, as described herein. In one or more embodiments, the one or more quantum dot ligands are provided on a surface of the quantum dot.

According to one or more embodiments, the quantum dot may have a single structure or a core-shell structure including a core and a shell, and the shell may be formed as a single layer or multiple layers. The core may include a first semiconductor material, and the shell may include a second semiconductor material. Each of the first semiconductor material and the second semiconductor may include one or more semiconductor materials. For example, when the shell is formed as two layers, a first layer may include a second-first semiconductor material and a second layer may include a second-second semiconductor material. In some embodiments, for example, when the shell is formed as three layers, a first layer may include a second-first semiconductor material, a second layer may include a second-second semiconductor material, and a third layer may include a second-third semiconductor material. The core and each shell may be made of different materials. When the shell includes multiple layers, some layers may be made of the same material. In some embodiments, one shell may include a plurality of semiconductor materials, and the semiconductor materials may have a concentration gradient inside the shell. In some embodiments, each of a plurality of shells may include a plurality of semiconductor materials, and the semiconductor materials may have a concentration gradient inside each shell.

According to one embodiment, the semiconductor materials may include a Group II-VI semiconductor, a Group III-V semiconductor, a Group IV-VI semiconductor, a Group IV semiconductor, or a combination thereof. The semiconductor materials may be a single element material, a binary component compound, a ternary component compound, a quaternary component compound, or a combination thereof. Each element included in a multi-element compound may be present in the core or shell at a substantially uniform or non-substantially uniform concentration. For example, a constituent element of the semiconductor material may have a concentration gradient inside the core or shell.

According to one or more embodiments, the first semiconductor material and the second semiconductor material may each independently include, for example,
ZnS, ZnSe, ZnTe, ZnO, MgSe, MgS, ZnSeS, ZnSeTe, ZnSTe, MgZnSe, MgZnS, or CdZnSeS;
GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AlPAs, AlPSb, InGaN, InGaP, InNP, InAlP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, InGaZnP, or InAIZnP;
TiO, GaO, GaS, GaSe, Ga₂Se₃, GaTe, InS, InSe, In₂S₃, In₂Se₃, or InTe;
InGaS₃ or InGaSe₃;
AgInS, AgInS₂, CuInS, CuInS₂, CuGaO₂, AgGaO₂, AgAlO₂, or AgInZnS;
SrSe, SnS, SnSe, SnTe, PbS, PbSe, or PbTe; SnSeS, SnSeTe, SnSTe, PbSeS, PbSeTe, PbSTe, SnPbS, SnPbSe, SnPbTe, SnPbSSe, SnPbSeTe, or SnPbSTe; and/or
Si, Ge, SiC, SiGe, or any combination thereof.

According to other embodiments, the first semiconductor material may include InP, InZnP, InGaP, ZnS, ZnSe, ZnTe, ZnSeS, ZnSeTe, PbSe, PbS, PbTe, AgInZnS, GaN, GaP, GaAs, InGaN, InAs, ZnO, or any combination thereof.

The second semiconductor material may include ZnS, ZnSe, ZnTe, ZnSeS, ZnSeTe, ZnO, InP, InS, GaP, GaN, GaO, ZnSeTe, InZnP, InGaP, InGaN, PbS, TiO, SrSe, or any combination thereof.

For example, the first semiconductor material may include InP, InGaP, ZnSeS, ZnSeTe, or any combination thereof.

The second semiconductor material may include ZnS, ZnSe, ZnSeS, ZnSeTe, or any combination thereof.

The quantum dots may have a diameter of, for example, about 1 nanometer (nm) to about 10 nm.

As the quantum dot ligand in the quantum dot composite, the described quantum dot ligand (compound) may be applied. The quantum dot composite may be formed through ligand exchange between the quantum dot ligand and a ligand formed in-situ on a surface of a quantum dot during synthesis of the quantum dot.

In the quantum dot composite, different functional groups of the quantum dot ligand may be bonded to different atoms on a surface of the quantum dot, respectively. In some embodiments, the different functional groups of the quantum dot ligand may be bonded together to the same atom on the surface of the quantum dot.

### Ink Composition

A quantum dot ink composition according to another aspect may include the described quantum dot composite and a monomer. A content (e.g., amount) of the monomer may be, for example, in a range of about 70 wt % to about 150 wt % with respect to 100 wt % of the quantum dot composite. According to one embodiment, the monomer may be an acrylate-based compound, for example, 1,6-hexanediol diacrylate.

According to one or more embodiments, the quantum dot ink composition may further include a solvent, a polymer resin, a curing agent, a dispersant, a scattering agent, or one or more suitable additives within a range that does not affect the physical properties of the quantum dot composite.

A quantum dot ink composition according to another aspect may include the described quantum dot composite and a solvent.

A content (e.g., amount) of the quantum dot composite may be in a range of about 0.1 wt % or more to about 60 wt % or less or, and specifically in a range of about 0.2 wt % or more to about 30 wt % or less or about 0.5 wt % or more to about 20 wt % with respect to the total weight of the quantum dot ink composition. When the above range is satisfied, the quantum dot ink composition is suitable to be utilized in preparing a functional layer such as an emission layer or a charge transport layer of a light-emitting device through a solution process.

As the solvent, any solvent capable of dispersing the described quantum dot composite may be selected.

### Examples of the Solvent May Include

alkylene glycol alkyl ether(s) selected from among ethylene glycol monomethyl ether, ethylene glycol monoethyl ether, ethylene glycol monopropyl ether, ethylene glycol monobutyl ether, propylene glycol monomethyl ether, and/or propylene glycol methyl ethyl ether,
diethylene glycol dialkyl ether(s), selected from among diethylene glycol dimethyl ether, diethylene glycol diethyl ether, diethylene glycol dipropyl ether, and/or diethylene glycol dibutyl ether,
alkylene glycol alkyl ether acetate(s), such as methyl cellosolve acetate, ethyl cellosolve acetate, propylene glycol monomethyl ether acetate, propylene glycol monoethyl ether acetate, and/or propylene glycol monopropyl ether acetate,
alkoxyalkyl acetate(s) selected from among methoxybutyl acetate and/or methoxypentyl acetate,
aromatic hydrocarbon(s) selected from among benzene, toluene, xylene, and/or mesitylene,
ketone(s) selected from among methyl ethyl ketone, acetone, methyl amyl ketone, methyl isobutyl ketone, and/or cyclohexanone;
alcohol(s) selected from among ethanol, propanol, butanol, hexanol, cyclohexanol, ethylene glycol, and/or glycerin,
ester(s) selected from among 3-ethoxypropionic acid ethyl ester, 3-methoxypropionic acid methyl ester, and 3-phenyl-propionic acid ethyl ester, cyclic ester(s) selected from among γ-butyrolactone and/or methoxybenzene (anisole), and/or
any combination thereof.

A content (e.g., amount) of the solvent may be in a range of about 40 wt % or more to about 99.9 wt % or less, for example, in a range of about 70 wt % or more to about 99.8 wt % or less, or for example, in a range of about 80 wt % or more to about 99.5 wt % or less, with respect to the total weight of the quantum dot ink composition. However, one or more embodiments are not limited thereto. When the above range is satisfied, the quantum dot composite may be well dispersed in the quantum dot ink composition and may have a quantum dot concentration suitable for a solution process.

According to one embodiment, the quantum dot ink composition may further include a monomer, a polymer resin, a curing agent, a dispersant, a scattering agent, or one or more suitable additives within a range that does not affect the physical properties of the quantum dot composite.

The quantum dot ink composition allows quantum dot composites in a composition to be uniformly dispersed without segregation to form a film having improved uniformity. The quantum dot ink composition may be utilized to form a film through any method suitable in the art including spin coating, inkjet printing, and/or the like.

### Light-Emitting Device

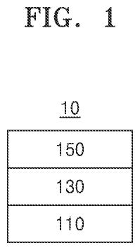

FIG. 1 is a schematic cross-sectional diagram illustrating a structure of a light-emitting device 10 according to one or more embodiments. The light-emitting device 10 may include a first electrode 110, an intermediate layer 130, and a second electrode 150. A substrate may be additionally provided under the first electrode 110 or on the second electrode 150 in FIG. 1.

The first electrode 110 may be an anode or a cathode and may be a light-transmitting, semi-light-transmitting, or reflective electrode. The second electrode 150 may be a cathode or an anode depending on the first electrode 110 and may be a light-transmitting, semi-light-transmitting, or reflective electrode.

The intermediate layer 130 may be provided on the first electrode 110. The intermediate layer 130 may include an emission layer.

In one or more embodiments, the emission layer may include a quantum dot composite according to the described embodiments. The emission layer may be formed from the quantum dot composition according to the described embodiments.

In other embodiments, the emission layer may include a host and a dopant. The dopant may include a phosphorescent dopant, a fluorescent dopant, or any combination thereof. In some embodiments, the emission layer may include a delayed fluorescent material. The delayed fluorescent material may serve as a host or dopant in the emission layer. The host may include a single host or a mixed host.

The intermediate layer 130 may further include a hole transport region and an electron transport region. The hole transport region or the electron transport region may be formed as a single layer or a plurality of layers. The hole transport region may include a hole injection layer, a hole transport layer, an emission auxiliary layer, an electron blocking layer, or any combination thereof. The electron transport region may include a buffer layer, a hole blocking layer, an electron adjustment layer, an electron transport layer, an electron injection layer, or any combination thereof. The layers may include a single material or a plurality of different materials.

The quantum dot composite according to the described embodiments may be included in the hole transport region or the electron transport region. A layer including the quantum dot composite may be formed from the quantum dot composition according to the described embodiments.

In some embodiments, the intermediate layer 130 may include i) two or more light-emitting units sequentially stacked between the first electrode 110 and the second electrode 150, and ii) a charge generation layer provided between the two or more light-emitting units. Each light-emitting unit may include an emission layer and may further include a hole transport region and an electron transport region. The quantum dot composite according to the above-described embodiments may be included in the emission layer, the hole transport region, or the electron transport region in the light-emitting unit. The quantum dot composite included in the emission layer, the hole transport region, or the electron transport region in the light-emitting unit may be formed from the quantum dot composition according to the described embodiments.

### Electronic Apparatus

The light-emitting device may be included in one or more suitable electronic apparatus(es). For example, an electronic apparatus including the light-emitting device may be a light-emitting apparatus, an authentication apparatus, and/or the like.

The electronic apparatus (for example, the light-emitting apparatus may further include i) a color filter, ii) a color conversion layer, or iii) a color filter and a color conversion layer in addition to the light-emitting device. The color filter and/or the color conversion layer may be provided in at least one traveling direction of light emitted from the light-emitting device. For example, light emitted from the light-emitting device may be blue light or white light. For a description of the light-emitting device, reference may be made to those described herein.

The electronic apparatus may include a first substrate. The first substrate may include a plurality of subpixel regions, the color filter may include a plurality of color filter regions corresponding to the plurality of subpixel regions, respectively, and the color conversion layer may include a plurality of color conversion regions corresponding to the plurality of subpixel regions, respectively.

A pixel defining layer may be provided between the plurality of subpixel regions to define each subpixel region.

The color filter may further include a plurality of color filter regions and light blocking patterns provided between the plurality of color filter regions, and the color conversion layer may further include a plurality of color conversion regions and light blocking patterns provided between (e.g., separating or defining) the plurality of color conversion regions.

The plurality of color filter regions (or the plurality of color conversion regions) may include a first region configured to emit first color light, a second region configured to emit second color light, and/or a third region configured to emit third color light, and the first color light, the second color light, and/or the third color light may have different maximum emission wavelengths. For example, the first color light may be red light, the second color light may be green light, and the third color light may be blue light. For example, the plurality of color filter regions (or the plurality of color conversion regions) may include quantum dots. For example, the first region may include a red quantum dot, the second region may include a green quantum dot, and the third region may not include (e.g., may exclude) a quantum dot. For a description of the quantum dot, reference may be made to those described herein. Each of the first region, the second region, and/or the third region may further include a scatterer.

The first and second regions including quantum dots may be formed utilizing a composition that includes a quantum dot composite of the present disclosure.

For example, the light-emitting device may be (e.g., configured) to emit first light, the first region may be (e.g., configured) to absorb the first light to emit first-first color light, the second region may be (e.g., configured) to absorb the first light to emit second-first color light, and the third region may be (e.g., configured) to absorb the first light to emit third-first color light. In this case, the first-first color light, the second-first color light, and the third-first color light may have different maximum emission wavelengths. For example, the first light may be blue light, the first-first color light may be red light, the second-first color light may be green light, and the third-first color light may be blue light.

The electronic apparatus may further include a thin film transistor (TFT) in addition to the light-emitting device described above. The TFT may include a source electrode, a drain electrode, and an active layer, and any one of the source electrode or the drain electrode may be electrically connected to any one of a first electrode or a second electrode of the light-emitting device.

The TFT may further include a gate electrode, a gate insulating film, and/or the like.

The active layer may include crystalline silicon, amorphous silicon, an organic semiconductor, an oxide semiconductor, and/or the like.

The electronic apparatus may further include an encapsulation unit configured to seal the light-emitting device. The encapsulation unit may be provided between the color filter and/or color conversion layer and the light-emitting device. The encapsulation unit may allow light from the light-emitting device to be emitted to the outside and concurrently may block or reduce external air and moisture from permeating into the light-emitting device. The encapsulation unit may be an encapsulation substrate including a transparent glass substrate or a plastic substrate. The encapsulation unit may be a thin film encapsulation layer including at least one layer selected from among an organic layer and/or an inorganic layer. When the encapsulation unit is the thin film encapsulation layer, the electronic apparatus may be flexible.

In addition to the color filter and/or the color conversion layer, one or more suitable functional layers may be additionally provided on the encapsulation unit according to the utilize of the electronic apparatus. Examples of the functional layer may include a touch screen layer, a polarization layer, and/or the like. The touch screen layer may be a resistive touch screen layer, a capacitive touch screen layer, or an infrared touch screen layer. The authentication apparatus may be, for example, a biometric authentication apparatus that identifies an individual utilizing biometric information about a body (for example, a fingertip, a pupil, or a vein).

The authentication apparatus may further include a biometric information collecting unit in addition to the light-emitting device described above.

The electronic apparatus may be applied to one or more suitable displays, a light source, an illuminator, a personal computer (for example, a mobile personal computer), a mobile phone, a digital camera, an electronic notebook, an electronic dictionary, an electronic game machine, a medical apparatus (for example, an electronic thermometer, a blood pressure monitor, a blood glucose meter, a pulse measuring apparatus, a pulse wave measuring apparatus, an electrocardiogram display apparatus, an ultrasonic diagnostic apparatus, or an endoscope display apparatus), a fish detector, one or more suitable measuring apparatuses, instruments (for example, instruments for vehicles, aircrafts, or ships), a projector, and/or the like.

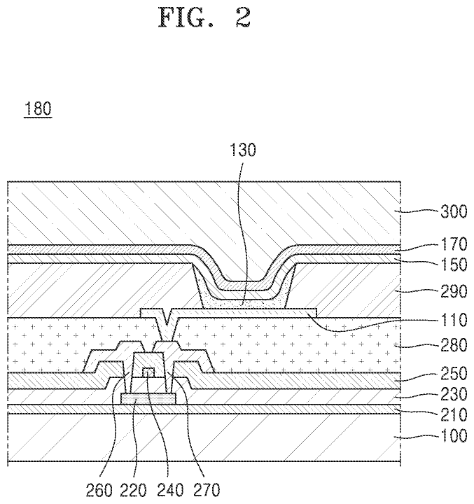

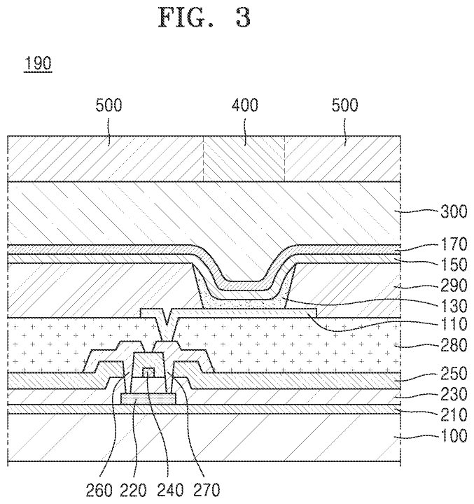

Description with Reference to FIGS. 2 and 3

FIG. 2 is a schematic cross-sectional view of an electronic apparatus 180 according to one embodiment of the disclosure.

The electronic apparatus 180 of FIG. 2 may include a substrate 100, a TFT, a light-emitting device, and an encapsulation unit 300 configured to seal the light-emitting device.

The substrate 100 may be a flexible substrate, a glass substrate, or a metal substrate. A buffer layer 210 may be provided on the substrate 100. The buffer layer 210 may serve to prevent or reduce penetration of impurities through the substrate 100 and provide a flat surface on the substrate 100.

The TFT may be provided on the buffer layer 210. The TFT may include an active layer 220, a gate electrode 240, a source electrode 260, and a drain electrode 270.

The active layer 220 may include an inorganic semiconductor such as silicon or polysilicon, an organic semiconductor, or an oxide semiconductor and may include a source region, a drain region, and a channel region.

A gate insulating film 230 may be provided on the active layer 220 to insulate the active layer 220 from the gate electrode 240, and the gate electrode 240 may be provided on the gate insulating film 230.

An interlayer insulating film 250 may be provided on the gate electrode 240. The interlayer insulating film 250 may be provided between the gate electrode 240 and the source electrode 260 and between the gate electrode 240 and the drain electrode 270, thereby serving to insulate the gate electrode 240 from the source electrode 260 and insulate the gate electrode 240 from the drain electrode 270.

The source electrode 260 and the drain electrode 270 may be provided on the interlayer insulating film 250. The interlayer insulating film 250 and the gate insulating film 230 may be formed to expose the source and drain regions of the active layer 220, and the source electrode 260 and the drain electrode 270 may be provided in contact with the exposed source and drain regions of the active layer 220.

The TFT may be electrically connected to the light-emitting device to drive the light-emitting device and may be covered and protected by a passivation layer 280. The passivation layer 280 may include an inorganic insulating layer, an organic insulating layer, or a combination thereof. The light-emitting device is provided on the passivation layer 280. The light-emitting device may include a first electrode 110, an intermediate layer 130, and a second electrode 150.

The first electrode 110 may be provided on the passivation layer 280. The passivation layer 280 may be provided to expose a certain region of the drain electrode 270 without covering the entirety of the drain electrode 270, and the first electrode 110 may be provided to be connected to the exposed certain region of the drain electrode 270.

A pixel defining film 290 including an insulating material may be provided on the first electrode 110. The pixel defining film 290 may expose a certain region of the first electrode 110, and the intermediate layer 130 may be formed in the exposed certain region. The pixel defining film 290 may be a polyimide or polyacrylic organic film. In one or more embodiments, at least a portion of the intermediate layer 130 may extend to an upper portion of the pixel defining film 290 and disposed in the form of a common layer(s).

The second electrode 150 may be provided on the intermediate layer 130, and a capping layer 170 may be additionally formed on the second electrode 150. The capping layer 170 may be formed to cover the second electrode 150.

An encapsulation unit 300 may be provided on the capping layer 170. The encapsulation unit 300 may be provided on the light-emitting device to protect the light-emitting device from moisture and/or oxygen. The encapsulation unit 300 may include an inorganic film including silicon nitride (SiNₓ), silicon oxide (SiOₓ), indium tin oxide, indium zinc oxide, or any combination thereof, an organic film including polyethylene terephthalate, polyethylene naphthalate, polycarbonate, polyimide, polyethylene sulfonate, polyoxymethylene, polyarylate, hexamethyldisiloxane, an acryl-based resin (for example, polymethyl methacrylate or a polyacrylic acid), an epoxy-based resin (for example, aliphatic glycidyl ether (AGE)), or an any combination thereof, or any combination of the inorganic film(s) and the organic film(s).

FIG. 3 is a schematic cross-sectional view of an electronic apparatus 190 according to other embodiments of the disclosure.

The electronic apparatus 190 of FIG. 3 may be the same as the electronic apparatus of FIG. 2, except that a light blocking pattern 500 and a functional region 400 are additionally provided on an encapsulation unit 300. The functional region 400 may be i) a color filter region, ii) a color conversion region, or iii) a combination of a color filter region and a color conversion region. According to one pr more embodiments, a light-emitting device included in the electronic apparatus 190 of FIG. 3 may be a tandem light-emitting device.

### Manufacturing Method

Each layer included in the hole transport region, the emission layer, each layer included in the electron transport region, and/or the like may be formed in specific regions utilizing one or more suitable methods including vacuum deposition, spin coating, casting, a Langmuir-Blodgett (LB) method, ink-jet printing, laser-printing, and/or laser-induced thermal imaging (LITI).

The color filter region, the conversion region, and/or the like may be formed in certain regions utilizing spin coating, casting, ink-jet printing, and/or the like.

When each layer included in the hole transport region, the emission layer, and each layer included in the electron transport are each formed through vacuum deposition, for example, the vacuum deposition may be performed under deposition conditions of a deposition temperature in a range of about 100° C. to about 500° C., a vacuum degree in a range of about 10⁻⁸ torr to about 10⁻³ torr, and a deposition rate in a range of about 0.01 angstrom per second (Å/sec) to about 100 Å/sec in consideration of a material to be included in a layer to be formed and a structure of the layer to be formed.

When each layer included in the hole transport region, the emission layer, and each layer included in the electron transport are each formed through spin coating, for example, the spin coating may be performed under coating conditions of a coating rate in a range of about 2,000 revolutions per minute (rpm) to about 5,000 rpm and a heat treatment temperature in a range of about 80° C. to about 200° C. in consideration of a material to be included in a layer to be formed and a structure of the layer to be formed.

A composition according to one embodiment of the disclosure present disclosure may be utilized in a solution process including spin coating, ink-jet printing, and/or the like.

The term “C₁-C₂₀ alkyl group” as utilized herein refers to a linear or branched aliphatic hydrocarbon monovalent group that has 1 to 20 carbon atoms, and examples thereof are a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, and/or the like. The term “C₁-C₂₀ alkylene group” as utilized herein refers to a divalent group having the same structure as the C₁-C₂₀ alkyl group.

The term “C₁-C₂₀ alkoxy group” as utilized herein refers to a monovalent group represented by —OA₁₁ (wherein A₁₁ is the C₁-C₂₀ alkyl group), and examples thereof are a methoxy group, an ethoxy group, an isopropyloxy group, and/or the like.

The term “C₆-C₂₀ aryl group” as utilized herein refers to a monovalent group having a carbocyclic aromatic system of 6 to 20 carbon atoms. Examples of the C₆-C₂₀ aryl group are a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, and/or the like. When the C₆-C₂₀ aryl group includes two or more rings, the rings may be condensed with each other.

The term “C₂-C₂₀ heteroaryl group” as utilized herein refers to a monovalent group having a heterocyclic aromatic system of 2 to 20 carbon atoms, further including, in addition to carbon atoms, at least one heteroatom, as ring-forming atoms. Examples of the C₂-C₂₀ heteroaryl group are a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, and/or the like. When the C₂-C₂₀ heteroaryl group includes two or more rings, the rings may be condensed with each other.

The term “C₇-C₂₀ aryl alkyl group” as utilized herein refers to -A₁₄A₁₅ (wherein A₁₄ is a C₁-C₁₄ alkylene group, and A₁₅ is a C₆-C₁₉ aryl group).

Depending on context, a divalent group may refer or be a polyvalent group (e.g., trivalent, tetravalent, etc., and not just divalent) per, e.g., the structure of a formula in connection with which of the terms are utilized.

Hereinafter, a quantum dot ligand, a quantum dot composite, and a light-emitting device according to one or more embodiments will be described in more detail with reference to Synthesis Examples and Examples. The wording “B was utilized instead of A” utilized in describing Synthesis Examples refers to that a molar equivalent of A was identical to a molar equivalent of B.

### EXAMPLES

### Synthesis 1 of Quantum Dot Ligand (Compound 1)

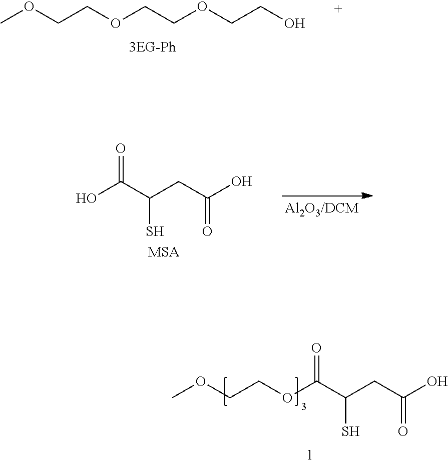

The materials 8.21 g (0.04 mol) of triethylene glycol monomethyl ether (3EG-Ph manufactured by TCI), 7.51 g (0.05 mol) of a mercaptosuccinic acid (MSA manufactured by TCI), and 2.5 g of Al₂O₃ (manufactured by Carlo Erba) were mixed into 100 mL of dichloromethane (DCM), put into a flask at room temperature (25° C.), and then stirred by maintaining a nitrogen atmosphere for 24 hours.

A solvent was evaporated under reduced pressure, and a product was dried and purified through column chromatography and recrystallization to obtain Compound 1.

### Example 1: Preparation of Ligand-Exchanged Quantum Dot Composite

One (1) g of InP/ZnSe/ZnS quantum dots coordinated with an oleic acid was added to a cyclohexyl acrylate solvent in a content (e.g., amount) of 25 wt % and stirred at room temperature for 1 hour to form a quantum dot dispersion. Then 0.158 g of Compound 1 was added dropwise to the quantum dot dispersion followed by stirring at a temperature of 70° C. for 2 hours to allow most of an oleic acid ligand to be substituted with a ligand of Compound 1.

Subsequently, a precipitate obtained by adding hexane in a content (e.g., amount) of 10 times that of the quantum dot dispersion and performing centrifugation at 9,500 rpm for 5 minutes was vacuum-dried to obtain a quantum dot composite.

### Comparative Example 1: Preparation of Ligand-Exchanged Quantum Dot Composite

A ligand-exchanged quantum dot composite was obtained in substantially the same manner as in Example 1, except that MPEG4-CH₂CH₂COOH (manufactured by PurePEG LLC) was utilized as a ligand for exchanging an oleic acid instead of Compound 1.

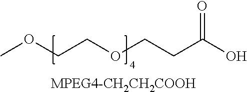

### Comparative Example 2: Preparation of Ligand-Exchanged Quantum Dot Composite

A ligand-exchanged quantum dot composite was obtained in substantially the same manner as in Example 1, except that MPEG5-SH (manufactured by PurePEG LLC) was utilized as a ligand for exchanging an oleic acid instead of Compound 1.

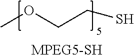

### Comparative Example 3: Preparation of Ligand-Exchanged Quantum Dot Composite

A ligand-exchanged quantum dot composite was obtained in substantially the same manner as in Example 1, except that 0.315 g of Compound 1 was added dropwise to a quantum dot dispersion instead of 0.158 g of Compound 1 to allow 60% of an oleic acid ligand to be substituted with a ligand of Compound 1.

### Preparation of Quantum Dot Ink Composition

Four quantum dot ink compositions were prepared from the four quantum dot composites. A quantity of 0.375 g of a quantum dot composite prepared in Example 1 or Comparative Examples 1, 2 or 3 was mixed with 0.526 g of 1,6-hexanediol diacrylate (HDDA) as a monomer followed by stirring at room temperature for 12 hours, and then 0.08 g of TiO₂ as a scattering agent and 0.01 g of a photopolymerization initiator (2,4,6-trimethylbenzoyldiphenyl phosphine oxide (TPO)) were added thereto and further stirred for 3 hours to prepare a quantum dot ink composition.

### Preparation of Quantum Dot Film

Four quantum dot films were prepared from the four quantum dot ink compositions. A quantum dot ink composition prepared as described from a quantum dot composite of Example 1 or Comparative Examples 1, 2 or 3 was applied to a thickness of 10 micrometers (μm) through spin coating, exposed to ultraviolet (UV) light, and then baked at a temperature of 180° C. for 30 minutes to prepare a quantum dot film.

### Evaluation of Reliability

A change ratio (%) (a) of a photoluminescence quantum yield (PLQY) of a quantum dot composite solution after ligand substitution to a PLQY of the quantum dot composite solution before ligand substitution was measured and shown in Table 1.

After a quantum dot ink composition was applied through spin coating, a change ratio (%) (b) of photoconversion efficiency (PCE) after baking to PCE before baking was measured and shown in Table 1 (heat resistance evaluation).

Light resistance of a film was evaluated by irradiating light of a blue light-emitting diode (LED) of 60 milliwatt (mW) for 500 hours onto a quantum dot film prepared through baking. A change ratio (%) (c) of PCE after irradiation of light of the blue LED to PCE before irradiation of light of the blue LED was measured and shown in Table 1.

The light resistance of the film was evaluated, whether the film was deteriorated over time (d) was checked qualitatively (e.g., with the naked eye) and shown in Table 1.

TABLE 1

| | Ligand | | Light | Change over |
|---|---|---|---|---|
| | exchange (a) | Baking (b) | irradiation (c) | time (d) |
| Example 1 | 105% | 100.1% | 99.4% | Good |
| Comparative | 101% | 85.0% | 104.2% | Good |
| Example 1 | | | | |
| Comparative | 102% | 99.0% | 67.9% | Thin film |
| Example 2 | | | | deterioration |
| Comparative | 90.7% | 96.5% | 66.3% | Thin film |
| Example 3 | | | | deterioration |

Referring to Table 1, a PLQY of the quantum dot composite of Example 1 was increased to 105% as compared with a quantum dot composite having an oleic acid ligand before ligand exchange. This shows that the PLQY is enhanced or more increased as compared with 101% and 102% of Comparative Examples 1 and 2. The film formed from the quantum dot composite of Example 1 has a PCE of 100.1% after baking and a PCE of 99.4% after light irradiation and thus has stability against baking and light irradiation. On the other hand, a film formed from the quantum dot composite of Comparative Example 1 has a PCE of 85.0% after baking and thus has low stability against baking. A film formed from the quantum dot composite of Comparative Example 2 has a PCE of 67.9% after light irradiation and thus has low stability against light irradiation.

PCE was measured utilizing QE-2100 [red blue light with a wavelength of 450 nm to 460 nm and an intensity of 0.012 uW/cm²/nm to 0.018 uW/cm²/nm] manufactured by Otsuka Electronics Co., Ltd.

An electronic apparatus including a quantum dot ligand having improved light resistance or heat resistance and a quantum dot composite including the same has high PCE.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the drawings, it will be understood by those of ordinary skill in the art that one or more suitable changes in form and details may be made therein without departing from the spirit and scope as defined by the following claims and equivalents thereof.

What is claimed is:

1. A quantum dot composite comprising:
a quantum dot; and
a quantum dot ligand on a surface of the quantum dot,
wherein the quantum dot ligand comprises:
a hydrophilic linking portion comprising one or more oxygen atoms;
a bonding portion linked to one side of the hydrophilic linking portion and comprising different functional groups bonded to the quantum dot; and
a terminal portion linked to the hydrophilic linking portion at a side opposite to the bonding portion, and
wherein the different functional groups are selected from among —COOH, —OH, —SH, and —NH₂.

2. The quantum dot composite of claim 1, wherein the quantum dot ligand is represented by Formula 1: 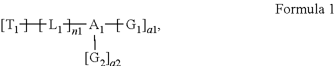
and
wherein, in Formula 1,
L₁ is the hydrophilic linking portion,
A₁ is the bonding portion,
G₁ and G₂ are the different functional groups,
T₁ is the terminal portion which is not bonded to the quantum dot,
n1 is an integer from 1 to 10,
a1 and a2 are each independently 1 or 2, and
a1+a2 is 3 or less.

3. The quantum dot composite of claim 1, wherein the hydrophilic linking portion comprises an ethylene glycol unit (CH₂CH₂O) or a propylene glycol unit (CH₂CH(CH₃)O or CH₂CH₂CH₂O).

4. The quantum dot composite of claim 1, wherein the bonding portion comprises a C₂-C₅ alkyl group or a C₂-C₅ alkenyl group.

5. The quantum dot composite of claim 4, wherein, in A₁, a carbon atom to which G₁ is bonded and a carbon atom to which G₂ is bonded are adjacent to each other.

6. The quantum dot composite of claim 4, wherein a C₁-C₃ moiety links a carbon atom to which G₁ is bonded and a carbon atom to which G₂ is bonded.

7. The quantum dot composite of claim 1, wherein the bonding portion comprises C(═O)C(*)HC(**)H₂, and
C(*) and C(**) represent carbon atoms to which the different functional groups are bonded.

8. The quantum dot composite of claim 2, wherein a combination of G₁ and G₂ is selected from among (—COOH, —SH), (—SH, —COOH), (—COOH, —OH), (—OH, —COOH), (—COOH, —NH₂), (—NH₂, —COOH), (—SH, —NH₂), and (—NH₂, —SH).

9. The quantum dot composite of claim 1, wherein the terminal portion comprises a hydroxyl group, an amine group, a sulfonic acid group, a phosphoric acid group, an ammonium group, a phosphonium group, a C₁-C₂₀ alkyl group, a C₁-C₂₀ alkoxy group, a C₆-C₂₀ aryl group, a C₂-C₂₀ heteroaryl group, or a C₇-C₂₀ aryl alkyl group.

10. The quantum dot composite of claim 1, wherein the quantum dot ligand comprises any one selected from among compounds below:

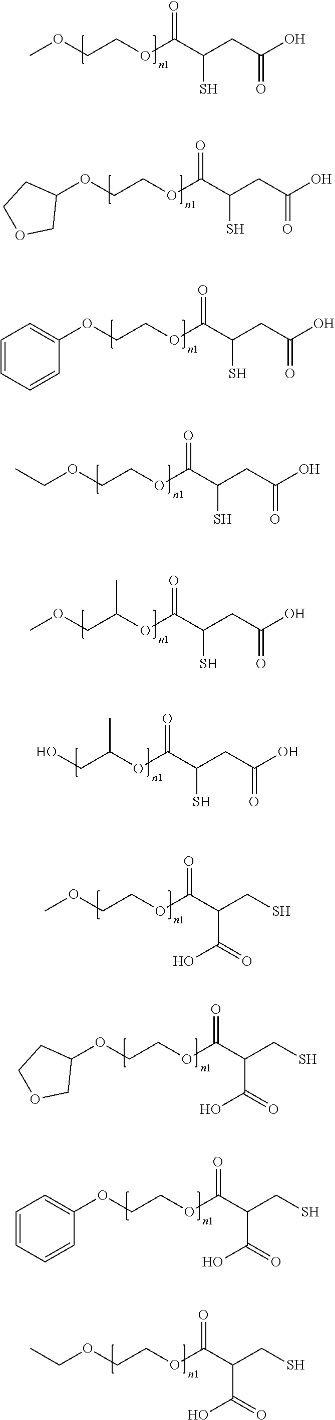

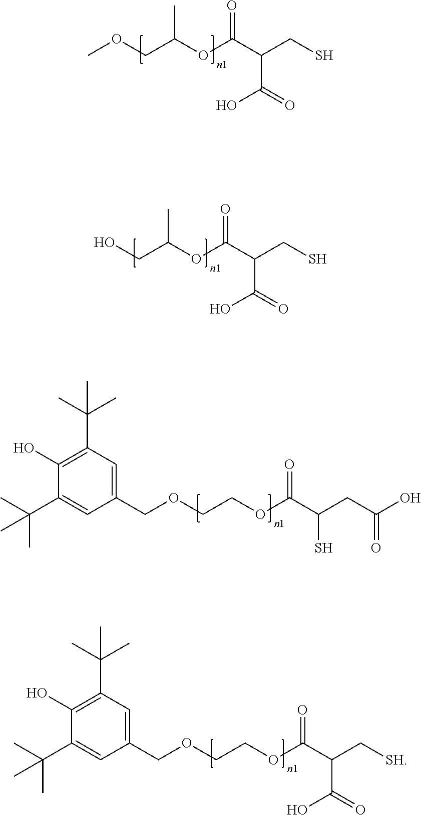

11. The quantum dot composite of claim 1, wherein the different functional groups are bonded to different atoms on the surface of the quantum dot, respectively.

12. The quantum dot composite of claim 1, wherein the different functional groups are bonded to one atom on the surface of the quantum dot.

13. The quantum dot composite of claim 1, wherein the quantum dot has a core-shell structure which comprises: a core comprising a first semiconductor material;
and a shell comprising a second semiconductor material and the shell around the core.

14. The quantum dot composite of claim 13, wherein the first semiconductor material and the second semiconductor material each independently comprise:
ZnS, ZnSe, ZnTe, ZnO, MgSe, MgS, ZnSeS, ZnSeTe, ZnSTe, MgZnSe, MgZnS, or CdZnSeS;
GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AlPAs, AlPSb, InGaN, InGaP, InNP, InAlP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, InGaZnP, or InAIZnP;
TiO, GaO, GaS, GaSe, Ga₂Se₃, GaTe, InS, InSe, In₂S₃, In₂Se₃, or InTe;
InGaS₃ or InGaSes;
AgInS, AgInS₂, CuInS, CuInS₂, CuGaO₂, AgGaO₂, AgAlO₂, or AgInZnS;
SrSe, SnS, SnSe, SnTe, PbS, PbSe, or PbTe; SnSeS, SnSeTe, SnSTe, PbSeS, PbSeTe, PbSTe, SnPbS, SnPbSe, SnPbTe, SnPbSSe, SnPbSeTe, or SnPbSTe; or
Si, Ge, SiC, SiGe, or any combination thereof.

15. An ink composition comprising the quantum dot composite of claim 1 and a crosslinkable monomer.

16. A light-emitting device comprising:
a first electrode;
a second electrode opposite to the first electrode; and
an intermediate layer between the first electrode and the second electrode,
wherein the intermediate layer comprises the quantum dot composite of claim 1.

17. An optical member comprising the quantum dot composite of claim 1.

18. The optical member of claim 17, wherein the optical member is a color conversion member.

19. An apparatus comprising the quantum dot composite of claim 1.

20. The apparatus of claim 19, further comprising a light source,
wherein the quantum dot composite is on a path of light to be emitted from the light source.
